(19) United States
(12) Patent Application Publication
(10) Pub. No.: US 2021/0118517 A1
(43) Pub. Date: Apr. 22, 2021

(54) MEMORY DEVICE

(71) Applicant: SK hynix Inc., Icheon-si Gyeonggi-do (KR)

(72) Inventor: Nam Gu KANG, Icheon-si Gyeonggi-do (KR)

(73) Assignee: SK hynix Inc., Icheon-si Gyeonggi-do (KR)

(21) Appl. No.: 16/894,035

(22) Filed: Jun. 5, 2020

(30) Foreign Application Priority Data
Oct. 21, 2019 (KR) 10-2019-0130968

(51) Int. Cl. G11C 16/34; G11C 16/10; G11C 16/26

(52) U.S. Cl. CPC G11C 16/3481; G11C 16/26; G11C 16/10; G11C 16/3495

(57) ABSTRACT

A memory device includes: a memory cell array including a plurality of memory blocks; peripheral circuits for performing a program operation on a selected memory block among the plurality of memory blocks and programming memory cells that are included in the selected memory block to a plurality of program states during the program operation; and a control logic for controlling the peripheral circuits to perform the program operation. The control logic counts a program pulse number that is used during the program operation and determines whether the selected memory block is a bad block, based on the counted program pulse number.

### CROSS-REFERENCE TO RELATED APPLICATION

The present application claims priority under 35 U.S.C. § 119(a) to Korean patent application number 10-2019-0130968, filed on Oct. 21, 2019, in the Korean Intellectual Property Office, the entire disclosure of which is incorporated herein by reference.

### BACKGROUND

### 1. Technical Field

The present disclosure generally relates to an electronic device, and more particularly, to a memory device capable of storing data.

### 2. Related Art

Recently, a paradigm for a computer environment has been transformed into ubiquitous computing, which enables computing systems to be used anywhere and at any time. This promotes the increased usage of portable electronic devices, such as mobile phones, digital cameras, notebook computers, and the like. Such portable electronic devices may generally include a memory system using a memory device, i.e., a data storage device. The data storage device is used as a main memory device or an auxiliary memory device of the portable electronic devices.

A data storage device, using a memory device, has excellent stability and durability, high information access speed, and low power consumption, since there is no mechanical driving part. In an example of memory systems having such advantages, the data storage device includes a Universal Serial Bus (USB) memory device, memory cards having various interfaces, a Solid State Drive (SSD), and the like.

### SUMMARY

In accordance with an aspect of the present disclosure, there is provided a memory device including: a memory cell array including a plurality of memory blocks; peripheral circuits configured to perform a program operation on a selected memory block among the plurality of memory blocks and configured to program memory cells that are included in the selected memory block to a plurality of program states during the program operation; and a control logic configured to control the peripheral circuits to perform the program operation, wherein the control logic is configured to count a program pulse number that is used during the program operation and configured to determine whether the selected memory block is a bad block based on the counted program pulse number.

In accordance with another aspect of the present disclosure, there is provided a memory device including: a memory cell array including a plurality of memory blocks; peripheral circuits configured to perform a program operation on a selected memory block among the plurality of memory blocks and configured to program memory cells that are included in the selected memory block to a plurality of program states during the program operation; and a control logic configured to control the peripheral circuits to perform the program operation, wherein the control logic is configured to set a plurality of program pulse count ranges by counting a program pulse number used during the program operation and configured to determine whether the selected memory block is a bad block based on a number of memory cells that are out of the plurality of set program pulse count ranges.

In accordance with still another aspect of the present disclosure, there is provided a memory device including: a memory block including a plurality of pages; peripheral circuits configured to perform a program operation on the memory block and configured to perform the program operation by sequentially selecting the plurality of pages during the program operation; and a control logic configured to control the peripheral circuits to perform the program operation, wherein the control logic is configured to count program pulses of each of the plurality of pages and configured to determine whether the memory block is a bad block based on the program pulses of each of the plurality of pages.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present.

Like reference numerals refer to like elements throughout.

FIG. 1 is a block diagram, illustrating a memory system, in accordance with an embodiment of the present disclosure.

FIG. 2 is a diagram, illustrating a memory device, shown in FIG. 1.

FIG. 3 is a diagram, illustrating a memory block, shown in FIG. 2.

FIG. 4 is a diagram, illustrating an embodiment of a three-dimensionally configured memory block.

FIG. 5 is a block diagram, illustrating an embodiment of a control logic, shown in FIG. 2.

FIG. 6 is a flowchart, illustrating an operating method of the memory system, in accordance with an embodiment of the present disclosure.

FIG. 7 is a threshold voltage distribution diagram, illustrating an erase state and program states of memory cells.

FIG. 8 is a block diagram, illustrating another embodiment of the control logic, shown in FIG. 2.

FIG. 9 is a flowchart, illustrating an operating method of the memory system, in accordance with another embodiment of the present disclosure.

FIG. 10 is a block diagram, illustrating still another embodiment of the control logic, shown in FIG. 2.

FIG. 11 is a flowchart, illustrating an operating method of the memory system, in accordance with still another embodiment of the present disclosure.

FIG. 12 is a diagram, illustrating another embodiment of the memory system.

FIG. 13 is a diagram, illustrating another embodiment of the memory system.

FIG. 14 is a diagram, illustrating another embodiment of the memory system.

FIG. 15 is a diagram, illustrating another embodiment of the memory system.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Hereinafter, exemplary embodiments of the present disclosure will be described in detail with reference to the accompanying drawings in order for those skilled in the art to be able to readily implement the technical spirit of the present disclosure.

Embodiments provide a memory device having improved data reliability.

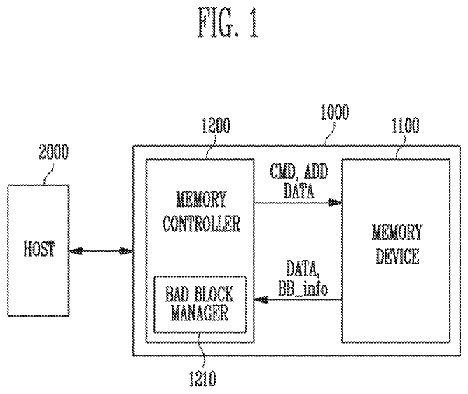

FIG. 1 is a block diagram, illustrating a memory system, in accordance with an embodiment of the present disclosure.

Referring to FIG. 1, the memory system 1000 may include a memory device 1100 that is configured to store data and a memory controller 1200 configured to control the memory device 1100 based on a host 2000.

The host 2000 may communicate with the memory system 1000 by using an interface protocol such as Peripheral Component Interconnect-Express (PCI-E), Advanced Technology Attachment (ATA), Serial ATA (SATA), Parallel ATA (PATA), or Serial Attached SCSI (SAS). In addition, interface protocols between the host 2000 and the memory system 1000 are not limited to the above-described examples, and may be one of other interface protocols such as a Universal Serial Bus (USB), a Multi-Media Card (MMC), an Enhanced Small Disk Interface (ESDI), and Integrated Drive Electronics (IDE).

The memory controller 1200 may control the operations of the memory system 1000 and control data exchange between the host 2000 and the memory device 1100. For example, the memory controller 1200 may program or read data by controlling the memory device 1100 based on a request from the host 2000. During a program operation, the memory controller 1200 transmits, to the memory device 1100, a command CMD corresponding to the program operation, an address ADD, and data DATA to be programmed. Also, in a read operation, the memory controller 1200 may receive and temporarily store data DATA that is read from the memory device 1100 and transmit the temporarily stored data DATA to the host 2000.

The memory controller 1200 may include a bad block manager 1210. The bad block manager 1210 may update and store information regarding a bad block among a plurality of memory blocks that is included in the memory device 1100 by receiving bad block information BB_info from the memory device 1100. The bad block manager 1210 may control the memory device 1100 such that the bad block is not selected in a general operation of the memory device 1100 based on the stored information on the bad block. In some embodiments, the memory device 1100 may include a Double Data Rate Synchronous Dynamic Random Access Memory (DDR SDRAM), a Low Power Double Data Rate 4 (LPDDR4) SDRAM, a Graphics Double Data Rate (GDDR) SRAM, a Low Power DDR (LPDDR), a Rambus Dynamic Random Access Memory (RDRAM), or a flash memory.

The memory device 1100 may perform a program, read, or erase operation based on the memory controller 1200.

In an embodiment of the present disclosure, the memory device 1100 may program memory cells that are included in a selected memory block to an erase state and a plurality of program states. The memory device 1100 may generate bad block information BB_info by determining whether the selected memory block is a normal memory block or a bad block based on a program pulse count value that is used during a program operation on the plurality of program states.

For example, the memory device 1100 may program memory cells that are included in a selected memory block to an erase state and a plurality of program states and generate bad block information BB_info by determining whether the corresponding memory block is a normal memory block or a bad block based on a difference value of the program pulse count that corresponds to a firstly program-passed memory cell and a program pulse count that corresponds to a lastly program-passed memory cell during a program operation of each of the plurality of program states.

For example, the memory device 1100 may program memory cells that are included in a selected memory block to an erase state and a plurality of program states and set a program pulse count range based on the program pulse number that is used during a program operation of each of the plurality of program states. The memory device 1100 may generate bad block information BB_info by comparing the number of memory cells out of the set program pulse count range to a reference memory cell number and determining whether the corresponding memory block is a normal memory block or a bad block.

For example, the memory device 1100 may program memory cells that are included in the selected memory block in a unit of a page and generate bad block information BB_info by determining whether the corresponding memory block is a normal memory block or a bad block based on the program pulse count used during a program operation on each page.

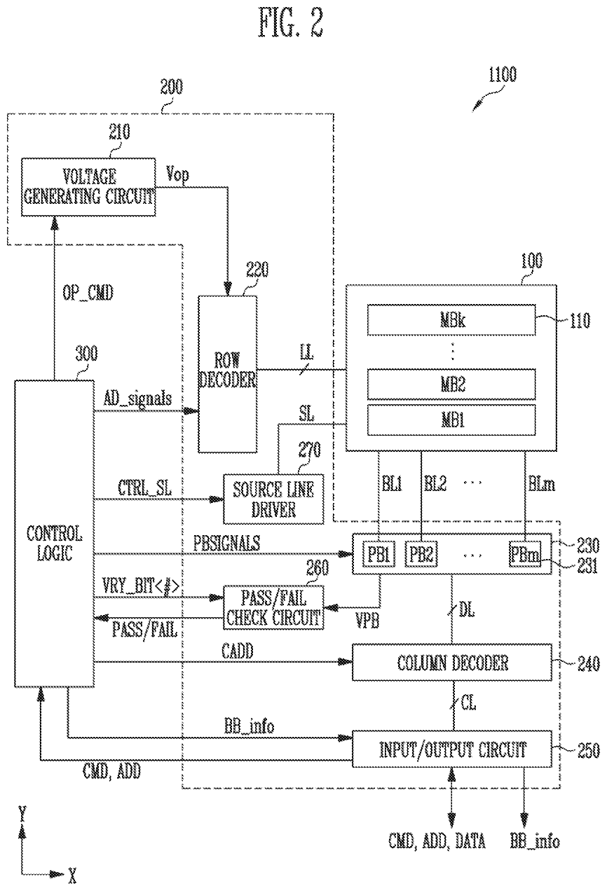

FIG. 2 is a diagram, illustrating the memory device shown in FIG. 1.

Referring to FIG. 2, the memory device 1100 may include a memory cell array 100 in which data is stored. The memory device 1100 may include peripheral circuits 200 that are configured to perform a program operation to store data in the memory cell array 100, a read operation to output the stored data, and an erase operation to erase the stored data. The memory device 1100 may include a control logic 300 which controls the peripheral circuits 200 based on the memory controller (1200 shown in FIG. 1).

The memory cell array 100 may include a plurality of memory blocks MB1 to MBk 110 (k is a positive integer). Local lines LL and bit lines BL1 to BLm (m is a positive integer) may be coupled to each of the memory blocks MB1 to MBk 110. For example, the local lines LL may include a first select line, a second select line, and a plurality of word lines that are arranged between the first and second select lines. Also, the local lines LL may include dummy lines that are arranged between the first select line and the word lines and between the second select line and the word lines. The first select line may be a source select line, and the second select line may be a drain select line. For example, the local lines LL may include word lines, drain and source select lines, and source lines SL. For example, the local lines LL may further include dummy lines. For example, the local lines LL may further include pipe lines. The local lines LL may be coupled to each of the memory blocks MB1 to MBk 110, and the bit lines BL1 to BLm may be commonly coupled to the memory blocks MB1 to MBk 110. The memory blocks MB1 to MBk 110 may be implemented in a two-dimensional or three-dimensional structure. For example, memory cells may be arranged in a direction that is parallel to the substrate in memory blocks 110 with a two-dimensional structure. For example, memory cells may be stacked in a direction that is vertical to the substrate in memory blocks 110 with a three-dimensional structure.

The peripheral circuits 200 may be configured to perform program, read, and erase operations on a selected memory block 110 based on the control logic 300. For example, the peripheral circuits 200 may include a voltage generating circuit 210, a row decoder 220, a page buffer group 230, a column decoder 240, an input/output circuit 250, a pass/fail check circuit 260, and a source line driver 270.

The voltage generating circuit 210 may generate various operating voltages Vop that are used for program, read, and erase operations based on an operation signal OP_CMD. Also, the voltage generating circuit 210 may selectively discharge the local lines LL based on the operation signal OP_CMD. For example, the voltage generating circuit 210 may generate a program voltage, a verify voltage, and a pass voltage based on the control logic 300.

The row decoder 220 may transfer the operating voltages Vop to the local lines LL that are coupled to the selected memory block 110 based on row decoder control signals AD_signals. For example, during a program operation, the row decoder 220 may apply the program voltage generated by the voltage generating circuit 210 to selected word lines among the local lines LL and apply the pass voltage generated by the voltage generating circuit 210 to the other unselected word lines, based on the row decoder control signals AD_signals.

The page buffer group 230 may include a plurality of page buffers PB1 to PBm 231 that is coupled to the bit lines BL1 to BLm. The page buffers PB1 to PBm 231 may operate based on page buffer control signals PBSIGNALS. For example, the page buffers PB1 to PBm 231 may temporarily store data that is to be programmed during a program operation and adjust the potential levels of the bit lines BL1 to BLm based on the temporarily stored data that is to be programmed. Also, the page buffers PB1 to PBm 231 may sense voltages or currents of the bit lines BL1 to BLm in a read or program verify operation.

The column decoder 240 may transfer data between the input/output circuit 250 and the page buffer group 230 based on a column address CADD. For example, the column decoder 240 may exchange data with the page buffers 231 through data lines DL, or the column decoder 240 may exchange data with the input/output circuit 250 through column lines CL.

The input/output circuit 250 may transfer a command CMD and an address ADD, which are received from the memory controller (1200 shown in FIG. 1), to the control logic 300, or the input/output circuit 250 may exchange data DATA with the column decoder 240. The input/output circuit 250 may transmit bad block information BB_info that is received from the control logic 300 to an exterior device (e.g., the memory controller 1200 shown in FIG. 1).

In a read operation or program verify operation, the pass/fail check circuit 260 may generate a reference current based on an allow bit VRY_BIT<#> and may output a pass signal PASS or a fail signal FAIL by comparing a sensing voltage VPB that is received from the page buffer group 230 to a reference voltage that is generated by the reference current. The sensing voltage VPB may be a voltage that is controlled based on the number of memory cells that are determined to pass during the program verify operation.

The source line driver 270 may be coupled to a memory cell that is included in the memory cell array 110 through a source line SL and may control a voltage that is applied to the source line SL. The source line driver 270 may receive a source line control signal CTRL_SL from the control logic 300 and may control a source line voltage, applied to the source line SL, based on the source line control signal CTRL_SL.

The control logic 300 may control the peripheral circuits 200 by outputting the operation signal OP_CMD, the row decoder control signals AD_signals, the page buffer control signals PBSIGNALS, and the allow bit VRY_BIT<#> based on the command CMD and the address ADD. Also, the control logic 300 may count a program pulse number during a program operation and may determine whether a memory block, on which the program operation is performed, is a bad block based on the counted program pulse number.

In an embodiment, the control logic 300 may check the program pulse count when a firstly program-passed memory cell is detected (hereinafter, referred to as a first program pulse count) and the program pulse count when a lastly program-passed memory cell is detected (hereinafter, referred to as a last program pulse count) during a program operation of each of a plurality of program states during a program operation of a selected memory block. The control logic 300 may generate bad block information BB_info by determining whether the corresponding memory block is a normal memory block or a bad block based on the difference value of the first program pulse count and the last program pulse count.

In another embodiment, the control logic 300 may calculate the average value of the program pulse number that is used during a program operation of each of the plurality of program states during a program operation of the selected memory block. The control logic 300 may set a program pulse count range that corresponds to each of the plurality of program states based on the average value. The control logic 300 may count the number of memory cells out of the set program pulse count range and may generate bad block information BB_info by comparing the counted number of memory cells to the reference memory cell number and by determining whether the corresponding memory block is a normal memory block or a bad block.

In still another embodiment, the control logic 300 may check program pulse counts, corresponding to a plurality of program states that is used during a program operation of each of a plurality of pages, included in a selected memory block. The control logic 300 may generate bad block information BB_info by comparing the checked program pulse counts that correspond to the plurality of program states of each of the plurality of pages and by determining whether the corresponding memory block is a normal memory block or a bad block.

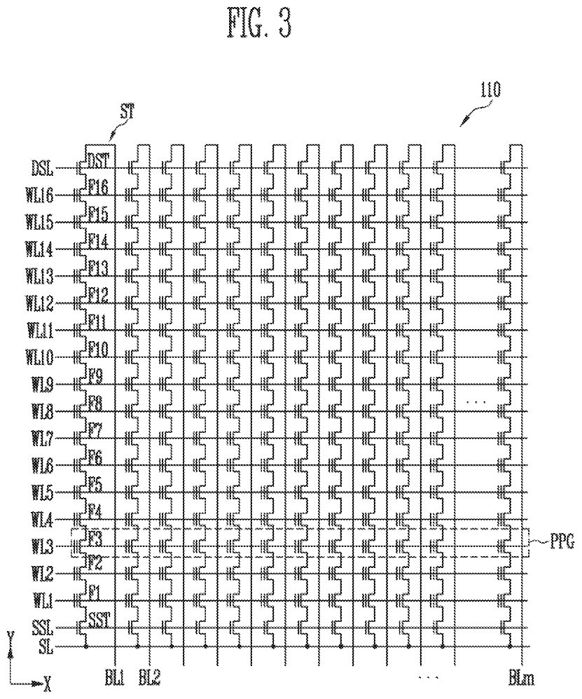

FIG. 3 is a diagram, illustrating the memory block, shown in FIG. 2.

Referring to FIG. 3, in the memory block 110, a plurality of word lines, arranged in parallel to one another, may be coupled between a first select line and a second select line. The first select line may be a source select line SSL, and the second select line may be a drain select line DSL. More specifically, the memory block 110 may include a plurality of strings ST that is coupled between the bit lines BL1 to BLm and a source line SL. The bit lines BL1 to BLm may be coupled to the strings ST, respectively, and the strings ST may be commonly coupled to the source line SL. The strings ST may be configured identically to one another, and therefore, a string ST that is coupled to a first bit line BL1 will be described in detail as an example.

The string ST may include a source select transistor SST, a plurality of memory cells F1 to F16, and a drain select transistor DST, all of which are coupled in series between the source line SL and the first bit line BL1. However, the number of source select transistors SST, memory cells, and drain select transistors are not limited thereto. For example, a different embodiment may include more than 16 memory cells.

A source of the source select transistor SST may be coupled to the source line SL, and a drain of the drain select transistor DST may be coupled to the first bit line BL1. The memory cells F1 to F16 may be coupled, in series, between the source select transistor SST and the drain select transistor DST. Gates of source select transistors SST that are included in different strings ST may be coupled to the source select line SSL, gates of drain select transistors DST that are included in different strings ST may be coupled to the drain select line DSL, and gates of the memory cells F1 to F16 that are included in different strings ST may be coupled to the plurality of word lines WL1 to WL16. A group of memory cells, coupled to the same word line among the memory cells, included in different strings ST, may be referred as a page PPG. Therefore, pages PPG, the number corresponding to that of the word lines WL1 to WL16, may be included in the memory block 110.

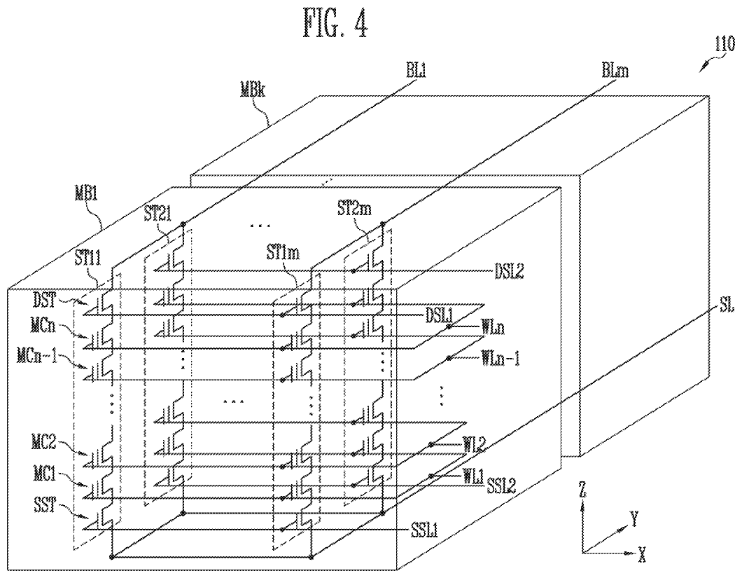

FIG. 4 is a diagram, illustrating an embodiment of a three-dimensionally configured memory block.

Referring to FIG. 4, the memory cell array 100 may include a plurality of memory blocks MB1 to MBk 110. The memory block 110 may include a plurality of strings ST11 to STim and ST21 to ST2m. In an embodiment, each of the plurality of strings ST11 to ST1m and ST21 to ST2m may be formed in an ‘I’ shape or ‘U’ shape. In a first memory block MB1, m strings may be arranged in a row direction (X direction). Although a case where two strings are arranged in a column direction (Y direction) is illustrated in FIG. 4, this is merely for convenience of description, and three or more strings may be arranged in the column direction (Y direction).

Each of the plurality of strings ST11 to ST1m and ST21 to ST2m may include at least one source select transistor SST, first to nth memory cells MCI to MCn, and at least one drain select transistor DST.

The source select transistor SST of each string may be coupled between a source line SL and memory cells MCI to MCp.

Source select transistors of strings that are arranged in the same row may be coupled to the same source select line. Source select transistors of strings ST11 to ST1m that are arranged on a first row may be coupled to a first source select line SSL1. Source select transistors of strings ST21 to ST2m that are arranged on a second row may be coupled to a second source select line SSL2. In another embodiment, the source select transistors of the strings ST11 to STim and ST21 to ST2m may be commonly coupled to one source select line.

The first to nth memory cells MCI to MCn of each string may be coupled, in series, to each other between the source select transistor SST and the drain select transistor DST. Gates of the first to nth memory cells MC1 to MCn may be coupled to first to nth word lines WL1 to WLn, respectively.

In an embodiment, at least one of the first to nth memory cells MC1 to MCn may be used as a dummy memory cell. When the dummy memory cell is provided, a voltage or current of a corresponding string may be stably controlled. Accordingly, the reliability of data storage in the memory block 110 may be improved.

The drain select transistor DST of each string may be coupled to a bit line and the memory cells MCI to MCn. Drain select transistors DST of strings arranged in the row direction may be coupled to a drain select line extending in the row direction. Drain select transistors DST of the strings ST11 to STim on the first row may be coupled to a first drain select line DSL1. Drain select transistors DST of the strings ST21 to ST2m on the second row may be coupled to a second drain select line DSL2.

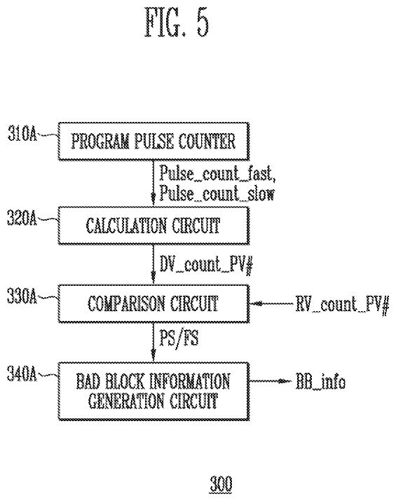

FIG. 5 is a block diagram, illustrating an embodiment of the control logic, shown in FIG. 2.

Referring to FIG. 5, the control logic 300 may include a program pulse counter 310A, a calculation circuit 320A, a comparison circuit 330A, and a bad block information generation circuit 340A.

The program pulse counter 310A may count a program pulse number during a program operation by using an Incremental Step Pulse Program (ISPP) method. The program pulse counter 310A may generate and output a first program pulse count signal Pulse_count_fast and a last program pulse count signal Pulse_count_slow of each of a plurality of program states. The first program pulse count signal Pulse_count_fast may be a signal that represents a program pulse count when a firstly program-passed memory cell (fast cell) is detected during a program verify operation based on a selected program state among the plurality of program states. On the other hand, the last program pulse count signal Pulse_count_slow may be a signal that represents a program pulse count when a lastly program-passed memory cell (slow cell) is detected during the program verify operation based on the selected program state.

The calculation circuit 320A may calculate and output a plurality of count difference values DV_count_PV# that correspond to each of the plurality of program states, based on the first program pulse count signal Pulse_count_fast and the last program pulse count signal Pulse_count_slow, which are received from the program pulse counter 310A. The plurality of count difference values DV_count_PV# may correspond to a count number difference between a first program pulse count and a last program pulse count of each of the plurality of program 1o states.

The comparison circuit 330A may output a pass signal PS or a fail signal FS that correspond to a bad block by comparing the plurality of count difference values DV_count_PV#, corresponding to each of the plurality of program states, to a plurality of reference difference values RV_count_PV#, corresponding to each of the plurality of program states. The plurality of reference difference values RV_count_PV# may be equal to each other or may be different from each other. For example, when all of the plurality of count difference values DV_count_PV# are equal to or smaller than the plurality of corresponding reference difference values RV_count_PV#, the comparison circuit 330A may output the pass signal PS. When at least one of the plurality of count difference values DV_count_PV# is greater than the plurality of corresponding reference difference values RV_count_PV#, the comparison circuit 330A may output the fail signal FS.

The bad block information generation circuit 340A may generate and output bad block information BB_info of a selected memory block on which a program operation is performed, based on the pass signal PS or the fail signal FS, which is received from the comparison circuit 330A. For example, when the pass signal PS is received from the comparison circuit 330A, the bad block Information generation circuit 340A may determine whether the selected memory block is a normal memory block and may generate and output the bad block information BB_info, including information that indicates that the selected memory block has been determined to be a normal memory block. On the other hand, when the fail signal FS is received from the comparison circuit 330A, the bad block information generation circuit 340A determines whether the selected memory block is a bad block and may generate and output the bad block information BB_info, including information that indicates that the selected memory block has been determined to be a bad block.

As described above, the control logic 300 may check a first program pulse count and a last program pulse count, corresponding to each of a plurality of program state during a program operation of a selected memory block, may calculate a plurality of count difference value DV_count_PV# that correspond to each of the plurality of program states by using the checked first program pulse count and the checked last program pulse count, may compare each of the plurality of count difference value DV_count_PV# to a corresponding reference difference value among a plurality of reference difference values RV_count_PV#, and may generate and output bad block information BB_info, including information that indicates that the selected memory block has been determined to be a normal memory block or a bad block, based on the comparison result.

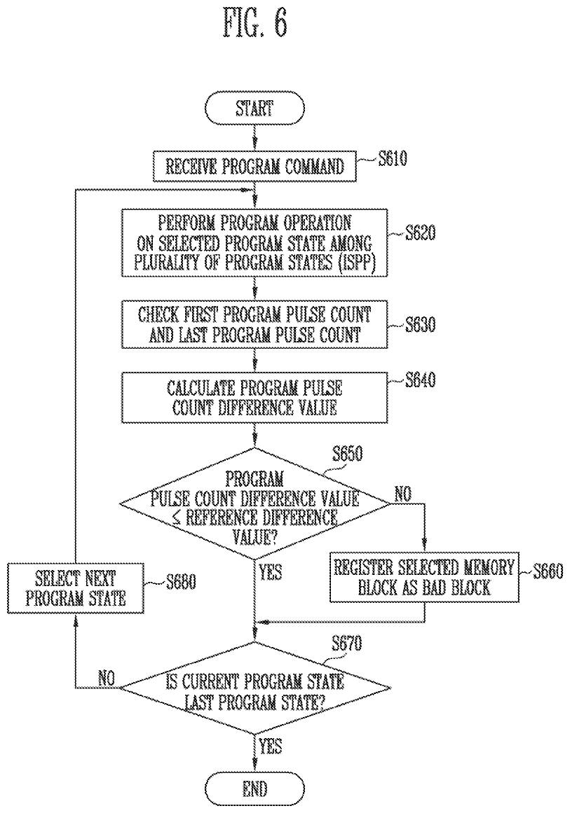

FIG. 6 is a flowchart, illustrating an operating method of the memory system, in accordance with an embodiment of the present disclosure.

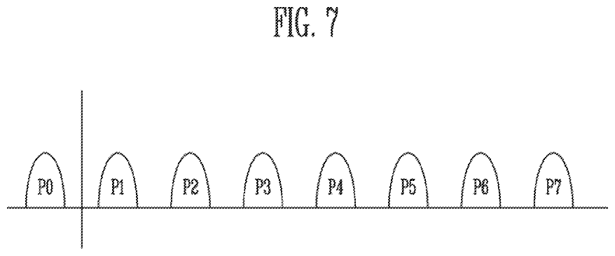

FIG. 7 is a threshold voltage distribution diagram, illustrating an erase state and program states of memory cells. Referring to FIG. 7, memory cells may be programmed from an erase state P0 to a plurality of program states P1 to P7 during a program operation.

The operating method of the memory system, in accordance with the embodiment of the present disclosure, will be described as follows with reference to FIGS. 1 to 7.

When a request that corresponds to a program operation is received from the host 2000, the memory controller 1200 may generate a program command CMD that corresponds to the program operation based on the request from the host 2000. The memory device 1100 may receive the program command CMD, an address ADD, and data DATA from the memory controller 1200 (S610).

The memory device 1100 may select a memory block (e.g., MB1) on which the program operation is to be performed, among a plurality of memory blocks MB1 to MBk, based on the received program command CMD and the received address ADD, may sequentially program the selected memory block (e.g., MB1) in a unit of a page, and may perform the program operation based on a selected program state among a plurality of program states during the program operation of a selected page PPG by using an ISPP method (S620). For example, the memory device 1100 may sequentially perform the program operation based on a program state with the lowest threshold voltage among a plurality of program states P1 to P7. For example, the memory device 1100 may perform the program operation by firstly selecting a first program state P1 among first to seventh program states P1 to P7, and perform the program operation by lastly selecting the seventh program state P7. That is, the memory device 1100 may perform the program operation by sequentially selecting the first to seventh program states P1 to P7.

During the program operation based on the selected program state, which is performed using the ISPP method, a program voltage application operation that applies a program voltage to memory cells, included in the selected page PPG, is performed. Memory cells that are determined to be program fail, among the memory cells that are included in the selected page PPG, may be detected by performing a program verify operation. When the memory cells that are determined to be the program fail are detected, the above-described operations may be re-performed from the program voltage application operation by using a new program voltage. When all of the memory cells that are included in the selected page PPG are determined to be program pass, it may be determined that the program operation based on the selected program state has been completed.

This will be described in more detail. The page buffer group 230 may temporarily store data DATA to be programmed, which is received through the input/output circuit 250 and the column decoder 240, based on page buffer control signals PBSIGNALS. The page buffer group 230 may apply a program inhibit voltage or a program allow voltage to the bit lines BL1 to BLm based on the temporarily stored data DATA. The program inhibit voltage may be a power voltage, and the program allow voltage may be a ground voltage or a voltage having a potential that is lower than that of the program inhibit voltage.

The voltage generating circuit 210 may generate and output operating voltages Vop that include a program voltage and a pass voltage, which are used during the program operation, based on an operation signal OP_CMD. The row decoder 220 may transfer the operating voltages Vop to local lines LL that are coupled to a selected memory block 110 based on row decoder control signals AD_signals. For example, the row decoder 220 may apply the program voltage that is generated by the voltage generating circuit 210 to a selected word line among the local lines LL based on the row decoder control signals AD_signals. The row decoder 220 may perform a program voltage application operation during the program operation by applying the pass voltage that is generated by the voltage generating circuit 210 to the other unselected word lines.

The page buffer group 230 may perform a program verify operation based on the page buffer signals PBSIGNALS, may apply the program allow voltage to a bit line that corresponds to a memory cell that is determined to be program fail as a result of the program verify operation, and may apply the program inhibit voltage to a bit line that corresponds to a memory cell that is determined to be program pass.

During the program verify operation, the pass/fail check circuit 260 may generate a reference current based on an allow bit VRY_BIT<#> and may output a pass signal PASS or a fail signal FAIL by comparing a sensing voltage VPB, received from the page buffer group 230, to a reference voltage, generated by the reference current. Accordingly, the control logic 300 may determine whether the program operation based on the selected program state has passed or failed.

When it is determined that the program operation has failed, the control logic 300 may control the voltage generation circuit 210 to generate a new program voltage with a voltage that is a step voltage higher than the previous program voltage and may control the peripheral circuits 200 to re-perform the above-described operations from the program voltage application operation. In addition, the program pulse counter 310A of the control logic 300 may count the number of times the program voltage, applied to a word line that corresponds to the selected page PPG, is applied during the program operation by using the ISPP method (i.e., the program pulse number).

When the program operation (S620) based on the selected program state is completed, the program pulse counter 310A may check a first program pulse count and a last program pulse count of the selected program state (S630) and may generate and output a first program pulse count signal Pulse_count_fast and a last program pulse count signal Pulse_count_slow based on the check result. The program pulse counter 310A may check, as the first program pulse count, the program pulse count when the memory cell on which the program verify operation on the corresponding program state has firstly passed is detected, based on the sensing voltage VPB that is output from the page buffer group 230. Also, the program pulse counter 310A may check, as the last program pulse count, the program pulse count when all the memory cells on which the program verify operation on the corresponding program state has passed are detected, based on the sensing voltage VPB that is output from the page buffer group 230.

The calculation circuit 320A may calculate and output the count difference value DV_count_PV#, corresponding to the selected program state, based on the first program pulse count signal Pulse_count_fast and the last program pulse count signal Pulse_count_slow, which are received from the program pulse counter 310A (S640).

The comparison circuit 330A may compare the count difference value DV_count_PV#, corresponding to the selected program state, to a reference difference value RV_count_PV# (S650). For example, the comparison circuit 330A may output a pass signal PS when the count difference value DV_count_PV# is equal to or smaller than the reference difference value RV_count_PV#, and the comparison circuit 330A may output a fail signal FS when the count difference value DV_count_PV# is greater than the reference difference value RV_count_PV#.

When the fail signal FS is output from the comparison circuit 330A, the count difference value DV_count_PV# being greater than the reference difference value RV_count_PV# (No), the bad block information generation circuit 340 may generate and output bad block information BB_info with information that indicates that the selected memory block MB1 has been determined to be a bad block based on the fail signal FS that is received from the comparison circuit 330C. Furthermore, the bad block information BB_info, output from the control logic 300, may be transmitted to the bad block manger 1210 of the memory controller 1200.

The bad block manager 1210 may update and register the selected memory block MB1 as a bad block by receiving the bad block information BB_info from the memory device 1100.

When the pass signal PS is output from the comparison circuit 330A, the count difference value DV_count_PV# being equal to or smaller than the reference difference value RV_count_PV# (Yes), the control logic 300 may determine whether the current program state is a last program state (e.g., P7) in which the memory cells are lastly programmed during the program operation (S670).

When it is determined in the above-described determination step S670 that the current program state is the last program state (Yes), the program operation may end. When it is determined in the above-described determination step S670 that the current program state is not the last program state (No), the next program state may be selected (S680), and the described-above steps may be re-performed at step S620.

In the above-described operating method, when the program operation on a selected page that is included in the selected memory block is completed, the above-described steps S620 to S680 may be re-performed by selecting the next page.

As described above, in accordance with the embodiment of the present disclosure, a first program pulse count and a last program pulse count, which correspond to each of a plurality of program states that are checked during a program operation of a selected memory block, and a plurality of count difference values DV_count_PV# that corresponds to each of the plurality of program states are calculated using the checked first program pulse count and the checked last program pulse count. Each of the plurality of count difference values DV_count_PV# may be compared to a corresponding reference difference value among a plurality of reference difference values RV_count_PV#, and the selected memory block may be determined to be a bad block, based on the comparison result. That is, a memory block having a large difference value based on the first program pulse count and the last program pulse count, during the program operation, is determined to be a bad block.

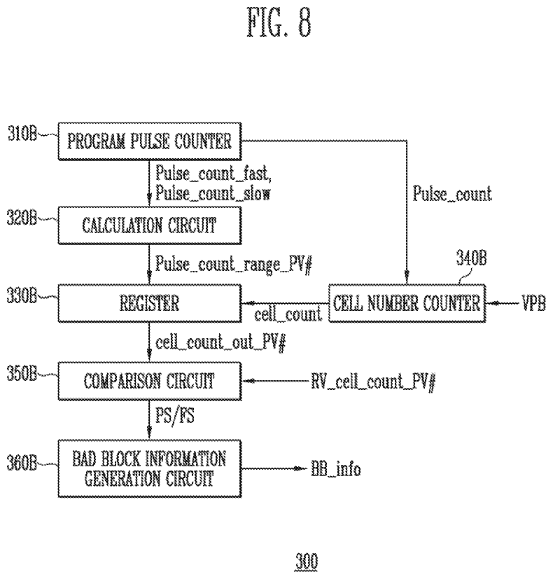

FIG. 8 is a block diagram, illustrating another embodiment of the control logic, shown in FIG. 2.

Referring to FIG. 8, the control logic 300, in accordance with the another embodiment of the present disclosure, may include a program pulse counter 310, a calculation circuit 320B, a register 330B, a cell number counter 340B, a comparison circuit 350B, and a bad block information generation circuit 360B.

The program pulse counter 310B may generate a program pulse count signal Pulse_count by counting a program pulse number during a program operation by using an Incremental Step Pulse Program (ISPP) method, and generates and outputs a first program pulse count signal Pulse_count_fast and a last program pulse count signal Pulse_count_slow of each of a plurality of program states. The first program pulse count signal Pulse_count_fast may be a signal representing a program pulse count when a firstly program-passed memory cell (fast cell) is detected during a program verify operation based on a selected program state among the plurality of program states, and the last program pulse count signal Pulse_count_slow may be a signal representing a program pulse count when a lastly program-passed memory cell (slow cell) is detected during the program verify operation based on the selected program state.

The calculation circuit 320B may calculate an average value of a program pulse count, corresponding to each of the plurality of program states, based on the first program pulse count signal Pulse_count_fast and the last program pulse count signal Pulse_count_slow, which are received from the program pulse counter 310B. The calculation circuit 320B may generate and output a program pulse count range signal Pulse_count_range_PV# by setting a program pulse count range, corresponding to each of the plurality of program states, based on the calculated average value of the program pulse count.

For example, when the first program pulse count is 5, the last program pulse count is 9, and the program pulse count range is 1 of the average value of the program pulse count, the average value of the program pulse count may be 7, and the program pulse count range may be 6 to 8.

The register 330B may receive and store the program pulse count range signal Pulse_count_range_PV#, output from the calculation circuit 320B, and may receive and store a cell count signal cell_count that is obtained by counting the number of program-passed memory cells in each program pulse that is output from the cell number counter 340B. Also, the register 330B may generate and output a cell count out signal cell_count_out_PV#, representing the number of memory cells that are out of the program pulse count range, based on the program pulse count range signal Pulse_count_range_PV# and the cell count signal cell_count.

The cell number counter 340B may generate and output a cell count signal cell_count by counting the number of memory cells that are determined to be program pass in each program pulse, based on the program pulse count signal Pulse_count that is received from the program pulse counter 310B and a sensing voltage VPB that is received from the page buffer group 230 during the program verify operation.

The comparison circuit 350B may receive a plurality of cell count out signals cell_count_out_PV# that correspond to each of the plurality of program states and a reference cell count signal RV_cell_count_PV# that correspond to a reference memory cell number of each of the plurality of program states, and the comparison circuit 350B may output a pass signal PS or a fail signal FS that corresponds to a bad block by comparing the number of memory cells that are out of the program pulse count range to the reference memory cell number. The reference memory cell numbers that correspond to the plurality of program states may be equal to or different from one another. When the number of memory cells that are out of the program pulse count range is equal to or smaller than the reference memory cell number, the comparison circuit 350B may output the pass signal PS. When the number of memory cells that are out of the program pulse count range is greater than the reference memory cell number, the comparison circuit 350B may output the fail signal FS.

The bad block information generation circuit 360B may generate and output bad block information BB_info of a selected memory block on which a program operation is performed based on the pass signal PS or the fail signal FS, which is received from the comparison circuit 350B. For example, when the pass signal PS is received from the comparison circuit 350B, the bad block information generation circuit 360B may determine whether the selected memory block is a normal memory block, and may generate and output the bad block information BB_info with information that indicates that the selected memory block has been determined to be a normal memory block. On the other hand, when the fail signal FS is received from the comparison circuit 350B, the bad block information generation circuit 360B may determine whether the selected memory block is a bad block, and may generate and output the bad block information BB_info with information that indicates that the selected memory block has been determined to be a bad block.

As described above, the control logic 300 may set a program pulse count range by calculating the program pulse count average value, corresponding to each of a plurality of program states, during a program operation of a selected memory block. The control logic 300 may generate and output bad block information BB_info with information that indicates that the selected memory block has been determined to be a normal memory block or a bad block based on the number of memory cells that are out of the set program pulse count range.

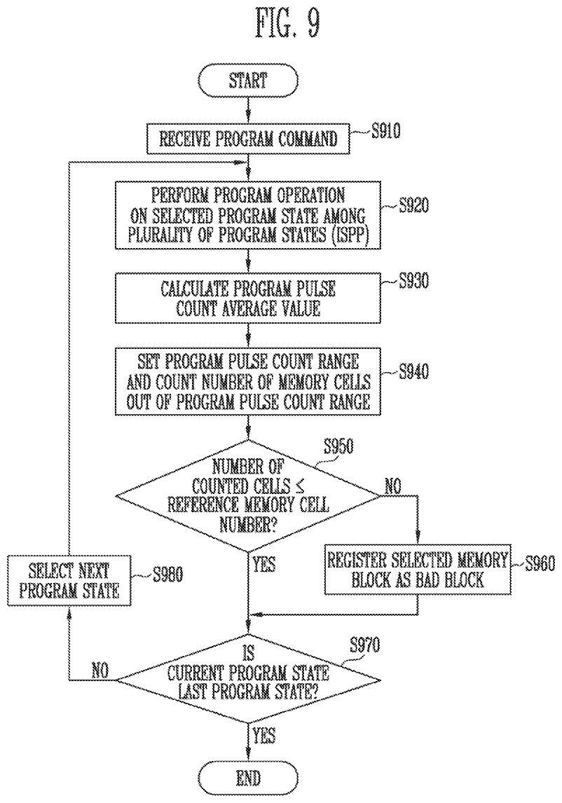

FIG. 9 is a flowchart, illustrating an operating method of the memory system, in accordance with another embodiment of the present disclosure.

The operating method of the memory system, in accordance with the another embodiment of the present disclosure, will be described as follows with reference to FIGS. 1 to 4, 7, and 9.

When a request, corresponding to a program operation, is received from the host 2000, the memory controller 1200 generates a program command CMD that corresponds to the program operation based on the request from the host 2000. The memory device 1100 receives the program command CMD, an address ADD, and data DATA to be programmed from the memory controller 1200 (S910).

The memory device 1100 may select a memory block (e.g., MB1) on which the program operation is to be performed among a plurality of memory blocks MB1 to MBk based on the received program command CMD and the received address ADD, sequentially program the selected memory block (e.g., MB1) in a unit of a page, and perform the program operation from a selected program state among a plurality of program states during the program operation of a selected page PPG by using an ISPP method (S920). For example, the memory device 1100 may sequentially perform the program operation based on a program state with the lowest threshold voltage among a plurality of program states P1 to P7. For example, the memory device 1100 may perform the program operation by firstly selecting a first program state P1 among first to seventh program states P1 to P7 and perform the program operation by lastly selecting the seventh program state P7. That is, the memory device 1100 may perform the program operation by sequentially selecting the first to seventh program states P1 to P7.

During the program operation based on the selected program state, which is performed using the ISPP method, a program voltage application operation of applying a program voltage to memory cells that are included in the selected page PPG is performed, and memory cells, among the memory cells, determined to be program fail that are included in the selected page PPG, may be detected by performing a program verify operation. When the memory cells, determined to be program fail, are detected, the above-described operations may be re-performed from the program voltage application operation by using a new program voltage. When all of the memory cells that are included in the selected page PPG are determined to be program pass, it may be determined that the program operation based on the selected program state has been completed.

This will be described in more detail. The page buffer group 230 may temporarily store the data DATA to be programmed, which is received through the input/output circuit 250 and the column decoder 240, based on page buffer control signals PBSIGNALS. The page buffer group 230 may apply a program inhibit voltage or a program allow voltage to the bit lines BL1 to BLm based on the temporarily stored data DATA. The program inhibit voltage may be a power voltage, and the program allow voltage may be a ground voltage or a voltage with a potential that is lower than that of the program inhibit voltage.

The voltage generating circuit 210 may generate and output operating voltages Vop with a program voltage and a pass voltage, which is are used during the program operation, based on an operation signal OP_CMD. The row decoder 220 may transfer the operating voltages Vop to local lines LL that are coupled to a selected memory block 110 based on row decoder control signals AD_signals. For example, the row decoder 220 may apply the program voltage that is generated by the voltage generating circuit 210 to a selected word line, among the local lines LL, based on the row decoder control signals AD_signals. The row decoder 220 may perform a program voltage application operation during the program operation by applying the pass voltage that is generated by the voltage generating circuit 210 to the other unselected word lines.

The page buffer group 230 may perform a program verify operation based on the page buffer signals PBSIGNALS, apply the program allow voltage to a bit line that corresponds to a memory cell that is determined to be program fail as a result of the program verify operation, and apply the program inhibit voltage to a bit line that corresponds to a memory cell that is determined to be program pass.

During the program verify operation, the pass/fail check circuit 260 may generate a reference current based on an allow bit VRY_BIT<#> and may output a pass signal PASS or a fail signal FAIL by comparing a sensing voltage VPB that is received from the page buffer group 230 to a reference voltage that is generated by the reference current. Accordingly, the control logic 300 may determine whether the program operation based on the selected program state has passed or failed.

When it is determined that the program operation has failed, the control logic 300 may control the voltage generation circuit 210 to generate a new program voltage with a voltage that is by a step voltage higher than the previous program voltage and may control the peripheral circuits 200 to re-perform the above-described operations from the program voltage application operation. In addition, the program pulse counter 310B of the control logic 300 may count the number of times the program voltage, applied to a word line that corresponds to the selected page PPG, is applied during the program operation by using the ISPP method (i.e., a program pulse number).

When the program operation (S920) based on the selected program state is completed, the program pulse counter 310B may generate a program pulse count signal Pulse_count based on a program pulse number during the program operation. The program pulse counter 310B may generate and output a first program pulse count signal Pulse_count_fast and a last program pulse count signal Pulse_count_slow of each of the plurality of program states. The calculation circuit 320B may calculate an average value of a program pulse count, corresponding to a selected program state, based on the first program pulse count signal Pulse_count_fast and the last program pulse count signal Pulse_count_slow, which are received from the program pulse counter 310B (S930).

The calculation circuit 320B may set a program pulse count range, corresponding to the selected program state, based on the calculated average value of the program pulse count. The register 330B may count the number of memory cells that are out of the program pulse count range based on a cell count signal cell_count for counting the number of program-passed memory cells in each program pulse that is output from the cell number counter 340B and a program pulse count range signal Pulse_count_range_PV# (S940).

The comparison circuit 350B may output a pass signal PS or a fail signal FS, corresponding to a bad block, by comparing the number of memory cells, out of the program pulse count range that correspond to the selected program state, to a reference memory cell number (S950). For example, when the number of memory cells that are out of the program pulse count range is equal to or smaller than the reference memory cell number, the comparison circuit 350B may output the pass signal PS. When the number of memory cells that are out of the program pulse count range is greater than the reference memory cell number, the comparison circuit 350B may output the fail signal FS.

When the fail signal FS is output from the comparison circuit 350B, the counted number of memory cells being greater than the reference memory cell number (No), the bad block information generation circuit 360B may generate and output bad block information BB_info with information that indicates that the selected memory block MB1 has been determined to be a bad block, based on the fail signal FS that is received from the comparison circuit 350B. Furthermore, the bad block information BB_info, output from the control logic 300, is transmitted to the bad block manager 1210 of the memory controller 1200. The bad block manager 1210 may update and register the selected memory block MB1 as a bad block by receiving the bad block information BB_info from the memory device 1100.

When the pass signal PS is output from the comparison circuit 350B, the counted number of memory cells being equal to or smaller than the reference memory cell number (Yes), the bad block information generation circuit 360B may determine whether the selected memory block is a normal memory block based on the pass signal PS that is received from the comparison circuit 350B. In addition, the control logic 300 may determine whether the current program state in which the program operation is performed is a last program state (e.g., P7) (S970).

When it is determined in the above-described determination step S970 that the current program state in which the program operation is performed is the last program state (Yes), the program operation may end. When it is determined in the above-described determination step S970 that the current program state in which the program operation is performed is not the last program state (No), the next program state may be selected (S980), and the described-above steps may be re-performed at step S920.

In the above-described operating method, when the program operation on a selected page that is included in the selected memory block is completed, the above-described steps S920 to S980 may be re-performed by selecting the next page.

As described above, in accordance with the another embodiment of the present disclosure, a program pulse count range may be set by calculating a program pulse count average value, corresponding to a program state during a program operation in a selected memory block, and the selected memory block is determined to be a bad block. That is, a memory block having a large number of memory cells that are out of the program pulse count range during the program operation is determined to be a bad block.

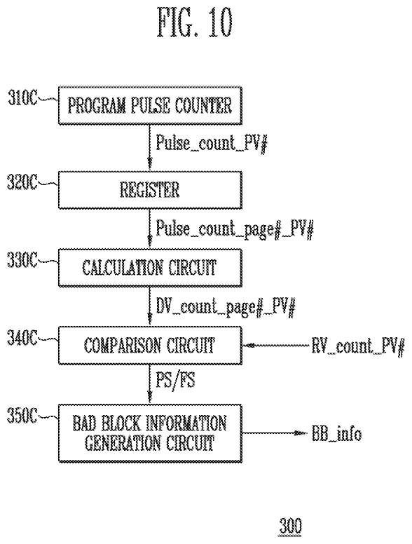

FIG. 10 is a block diagram, illustrating still another embodiment of the control logic, shown in FIG. 2.

Referring to FIG. 10, the control logic 200, in accordance with the still another embodiment of the present disclosure, may include a program pulse counter 310C, a register 320C, a calculation circuit 330C, a comparison circuit 340C, and a bad block information generation circuit 350C.

The program pulse counter 310C may count a program pulse number during a program operation by using an Incremental Step Pulse Program (ISPP) method. The program pulse counter 310C may generate a program pulse count Pulse_count_PV# of each of a plurality of program states by using a first program pulse count and a last program pulse count of each of the plurality of program states. The program pulse count Pulse_count_PV# may be an average count of program pulses used during the program operation of each program state. The program pulse count Pulse_count_PV# may include an average program pulse count that corresponds to each of first to seventh program states P1 to P7. The first program pulse count may be a program pulse count when a firstly program-passed memory cell (fast cell) is detected, during a program verify operation, based on a selected program state among the plurality of program states. The last program pulse count may be a program pulse count when a lastly program-passed memory cell (slow cell) is detected, during the program verify operation, based on the selected program state.

The register 320C may receive and store a program pulse count Pulse_count_PV# from the program pulse counter 310C during the program operation of each of the plurality of pages that is included in a selected memory block and may output a page program pulse count Pulse_count_page#_PV# based on the stored program pulse count Pulse_count_PV# of each page. The page program pulse count Pulse_count_page#_PV# may include the program pulse count Pulse_count_PV# of each of all the pages that is included in the selected memory block.

The calculation circuit 330C may receive a page program pulse count Pulse_count_page#_PV# from the register 320C and may calculate a page count difference value DV_count_page#_PV# based on the page program pulse count Pulse_count_page#_PV#. For example, the calculation circuit 330C may calculate an average value of program counts of all pages that corresponds to each program state based on the page program pulse count Pulse_count_page#_PV#, and the calculation circuit 330C may generate a page count difference value DV_count_page#_PV# of each page by calculating the difference between the average value and the program count of each page.

The comparison circuit 340C may output a pass signal or a fail signal, corresponding to a bad block, by comparing the page count difference value DV_count_page#_PV# to a reference difference value RV_count_PV#. For example, the comparison circuit 340C may output the pass signal PS when page count difference values DV_count_page#_PV# of all the pages are equal to or smaller than the reference difference value RV_count_PV#, and the comparison circuit 340C may output the fail signal FS when a page count difference value DV_count_page#_PV# of at least one page is greater than the reference difference value RV_count_PV#.

The bad block information generation circuit 350C may generate and output bad block information BB_info of a selected memory block on which a program operation is performed based on the pass signal PS or the fail signal FS, which is received from the comparison circuit 340C. For example, when the pass signal PS is received from the comparison circuit 340C, the bad block information generation circuit 350C may determine whether the selected memory block is a normal memory block, and the bad block information generation circuit 350C may generate and output the bad block information BB_info with information that indicates that the selected memory block has been determined to be a normal memory block. On the other hand, when the fail signal FS is received from the comparison circuit 340C, the bad block information generation circuit 350C may determine whether the selected memory block is a bad block, and the bad block information generation circuit 350C may generate and output the bad block information BB_info with information that indicates that the selected memory block has been determined to be a bad block.

As described above, the control logic 300, in accordance with the still another embodiment of the present disclosure, may check the program pulse counts that correspond to a plurality of program states used during a program operation of each of a plurality of pages, included in a selected memory block, and may generate bad block information BB_info by determining whether the selected memory block is a bad block when at least one page is detected, in which a difference between an average value of the checked program pulse counts, corresponding to the plurality of program states of each of the plurality of pages and a program pulse count of each page, exceeds a reference value.

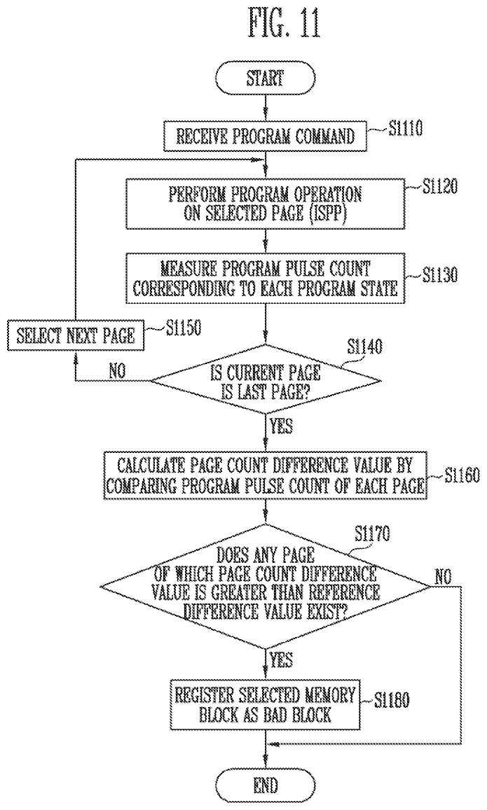

FIG. 11 is a flowchart, illustrating an operating method of the memory system, in accordance with still another embodiment of the present disclosure.

The operating method of the memory system, in accordance with the still another embodiment of the present disclosure, will be described as follows with reference to FIGS. 1 to 4, 7, 10, and 11.

When a request, corresponding to a program operation, is received from the host 2000, the memory controller 1200 may generate a program command CMD that corresponds to the program operation, based on the request from the host 2000. The memory device 1100 may receive the program command CMD, an address ADD, and data DATA to be programmed from the memory controller 1200 (S1110).

The memory device 1100 may perform a program operation, using an Incremental Step Pulse Program (ISPP) method, by selecting one page among a plurality of pages so as to select a memory block (e.g., MB1) on which the program operation is to be performed among a plurality of memory blocks MB1 to MBk based on the received program command CMD and the received address ADD and sequentially programming the selected memory block (e.g., MB1) in a unit of a page (S1120). For example, the memory device 1100 may sequentially perform the program operation based on a program state with the lowest threshold voltage among a plurality of program states P1 to P7. For example, the memory device 1100 may perform the program operation by firstly selecting a first program state P1 among first to seventh program states P1 to P7, and the memory device 1100 may perform the program operation by lastly selecting the seventh program state P7. That is, the memory device 1100 may perform the program operation by sequentially selecting the first to seventh program states P1 to P7.

During the program operation using the ISPP method, a program voltage application operation of applying a program voltage to memory cells that are included in a selected page PPG may be performed, and memory cells determined to be program fail among the memory cells that are included in the selected page PPG may be detected by performing a program verify operation. When the memory cells that are determined to be program fail are detected, the above-described operations may be re-performed from the program voltage application operation by using a new program voltage. When all the memory cells that are included in the selected page PPG are determined to be program pass, it may be determined that the program operation based on the selected program state has been completed.

This will be described in more detail. The page buffer group 230 may temporarily store data DATA to be programmed, which is received through the input/output circuit 250 and the column decoder 240, based on page buffer control signals PBSIGNALS, and the page buffer group 230 may apply a program inhibit voltage or a program allow voltage to the bit lines BL1 to BLm based on the temporarily stored data DATA. The program inhibit voltage may be a power voltage, and the program allow voltage may be a ground voltage or a voltage having a potential that is lower than that of the program inhibit voltage.

The voltage generating circuit 210 may generate and output operating voltages Vop with a program voltage and a pass voltage, which are used during the program operation, based on an operation signal OP_CMD. The row decoder 220 may transfer the operating voltages Vop to local lines LL that are coupled to a selected memory block 110 based on row decoder control signals AD_signals. For example, the row decoder 220 may apply the program voltage that is generated by the voltage generating circuit 210 to a selected word line, among the local lines LL, based on the row decoder control signals AD_signals. The row decoder 220 may perform a program voltage application operation during the program operation by applying the pass voltage that is generated by the voltage generating circuit 210 to the other unselected word lines.

The page buffer group 230 may perform a program verify operation based on the page buffer signals PBSIGNALS, apply the program allow voltage to a bit line that corresponds to a memory cell that is determined to be program fail as a result of the program verify operation, and apply the program inhibit voltage to a bit line that corresponds to a memory cell that is determined to be program pass.

During the program verify operation, the pass/fail check circuit 260 may generate a reference current based on an allow bit VRY_BIT<#>, and the pass/fail check circuit 260 may output a pass signal PASS or a fail signal FAIL by comparing a sensing voltage VPB that is received from the page buffer group 230 to a reference voltage that is generated by the reference current. Accordingly, the control logic 300 may determine whether the program operation based on the selected program state has passed or failed.

When it is determined that the program operation has failed, the control logic 300 may control the voltage generation circuit 210 to generate a new program voltage with a voltage that is by a step voltage higher than the previous program voltage and may control the peripheral circuits 200 to re-perform the above-described operations from the program voltage application operation. In addition, the program pulse counter 310B of the control logic 300 may count the number of times the program voltage, applied to a word line that corresponds to the selected page PPG, is applied during the program operation by using the ISPP method (i.e., a program pulse number).

The program pulse counter 310C may generate a program pulse count Pulse_count_PV# that corresponds to the plurality of program states of the selected page (S1130). That is, the program pulse counter 310C may generate a program pulse count Pulse_count_PV# by measuring the average count of program pulses that are used during the program operation of each program state of the selected page. The register 320C may receive and store the program pulse count Pulse_count_PV# from the program pulse counter 310C during the program operation of each of the plurality of pages that is included in the selected memory block.

When the program operation of the selected page is completed, the control logic 300 may check whether the current page is a last page during the program operation (S1140).

As a result of the above-described step S1140, when the current page of which the program operation has been completed is not the last page (No), the next page may be selected (S1150), and the above-described steps may be re-performed at step S1120.

As a result of the above-described step S1140, when the current page of which the program operation has been completed is the last page (Yes), the comparison circuit 340C may calculate a page count difference value DV_count_page#_PV# based on the program pulse count Pulse_count_PV# of each page, which is received from the program pulse counter 310C and stored during the program operation of each page (S1160).

The comparison circuit 340C may check whether a page exists that has a page count difference value DV_count_page#_PV# that is greater than a reference difference value RV_count_PV# by comparing the page count difference value DV_count_page#_PV# to the reference difference value RV_count_PV# (S1170). For example, the comparison circuit 340C may generate and output a pass signal PS when the page count difference values DV_count_page#_PV# of all of the pages are equal to or smaller than the reference difference value RV_count_PV#. The comparison circuit 340C may generate and output a fail signal FS when the page count difference value DV_count_page#_PV# of at least one page is greater than the reference difference value RV_count_PV#.

As a result of the above-described step S1170, when a page exists that has a page count difference value DV_count_page#_PV# that is greater than the reference difference value RV_count_PV# (Yes), the bad block information generation circuit 350 may determine whether the selected memory block is a bad block based on the fail signal FS received from the comparison circuit 340C. The bad block information generation circuit 350 may generate and output bad block information BB_info with information that indicates that the selected memory block has been determined to be a bad block. The bad block manager 1210 may update and register the selected memory block MB1 as a bad block by receiving the bad block information BB_info from the memory device 1100.

As a result of the above-described step S1170, when no page exists that has a page count difference value DV_count_page#_PV# that is greater than the reference difference value RV_count_PV# (No), the bad block information generation circuit 350C may determine whether the selected memory block is a normal memory block based on the pass signal PS that is received from the comparison circuit 340C, and may end the program operation.

In the above-described embodiment, the difference between the average value of program pulse counts, corresponding to a plurality of program states, and the program pulse count of each page is compared by checking the program pulse count of each of the plurality of program states. However, a difference between the average value of program pulse counts and the program pulse count of each page may be compared by only checking the program pulse counts that correspond to a program state (e.g., PV1), corresponding to the lowest threshold voltage distribution and a program state (e.g. PV7), corresponding to the highest threshold voltage distribution, among a plurality of program states.

As described above, in accordance with the still another embodiment of the present disclosure, program pulse counts, corresponding to a plurality of program states used during a program operation of each of a plurality of pages that is included in a selected memory block, may be checked, and the corresponding memory block may be determined to be a bad block when at least one page in which the difference between the average value of the checked program pulse counts, corresponding to the plurality of program states of each of the plurality of pages, and a program pulse count of each page exceeds a reference value is detected.

In the above-described embodiments of the present disclosure, a triple-level cell (TLC) program method in which the number of threshold voltage distributions of programmed memory cells is 8 (P0 to P7) has been described. However, the present disclosure may be applied to a multi-level cell (MLC) program method with the number of threshold voltage distributions being 4, a quad-level cell (QLC) program method with the number of threshold voltage distributions being 16, and the like.

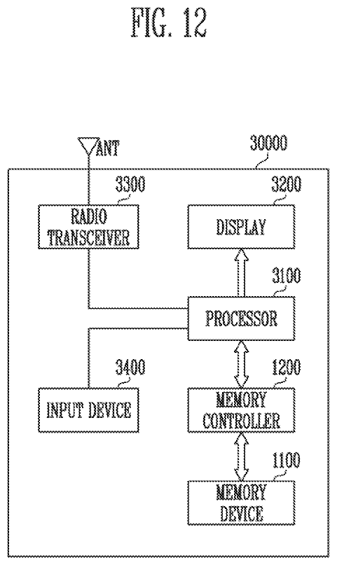

FIG. 12 is a diagram, illustrating another embodiment of the memory system.

Referring to FIG. 12, the memory system 30000 may be implemented as a cellular phone, a smart phone, a tablet PC, a personal digital assistant (PDA), or a wireless communication device. The memory system 30000 may include a memory device 1100 and a memory controller 1200 capable of controlling an operation of the memory device 1100. The memory controller 1200 may control a data access operation of the memory device 1100, e.g., a program operation, an erase operation, a read operation, or the like based on a processor 3100.

Data programmed in the memory device 1100 may be output through a display 3200 based on the memory controller 1200.

A radio transceiver 3300 may transmit/receive radio signals through an antenna ANT. For example, the radio transceiver 3300 may change a radio signal received through the antenna ANT into a signal that can be processed by the processor 3100. Therefore, the processor 3100 may process a signal output from the radio transceiver 3300 and transmit the processed signal to the memory controller 1200 or the display 3200. The memory controller 1200 may transmit the signal processed by the processor 3100 to the memory device 1100. Also, the radio transceiver 3300 may change a signal output from the processor 3100 into a radio signal, and output the changed radio signal to an external device through the antenna ANT. An input device 3400 is a device capable of inputting a control signal for controlling an operation of the processor 3100 or data to be processed by the processor 3100, and may be implemented as a pointing device such as a touch pad or a computer mount, a keypad, or a keyboard. The processor 3100 may control an operation of the display 3200 such that data output from the memory controller 1200, data output from the radio transceiver 3300, or data output from the input device 3400 can be output through the display 3200.

In some embodiments, the memory controller 1200 capable of controlling an operation of the memory device 1100 may be implemented as a part of the processor 3100, or be implemented as a chip separate from the processor 3100. Also, the memory controller 1200 may be implemented with the memory controller 1200 shown in FIG. 1, and the memory device 1100 may be implemented with the memory device 1100 shown in FIG. 2.

FIG. 13 is a diagram, illustrating another embodiment of the memory system.

Referring to FIG. 13, the memory system 40000 may be implemented as a personal computer (PC), a tablet PC, a net-book, an e-reader, a personal digital assistant (PDA), a portable multi-media player (PMP), an MP3 player, or an MP4 player.

The memory system 40000 may include a memory device 1100 and a memory controller 1200 capable of controlling a data processing operation of the memory device 1100.

A processor 4100 may output data stored in the memory device 1100 through a display 4300 based on data input through an input device 4200. For example, the input device 4200 may be implemented as a pointing device such as a touch pad or a computer mouse, a keypad, or a keyboard.

The processor 4100 may control overall operations of the memory system 40000, and control an operation of the memory controller 1200. In some embodiments, the memory controller 1200 capable of controlling an operation of the memory device 1100 may be implemented as a part of the processor 4100, or be implemented as a chip separate from the processor 4100. Also, the memory controller 1200 may be implemented with the memory controller 1200 shown in FIG. 1, and the memory device 1100 may be implemented with the memory device 1100 shown in FIG. 2.

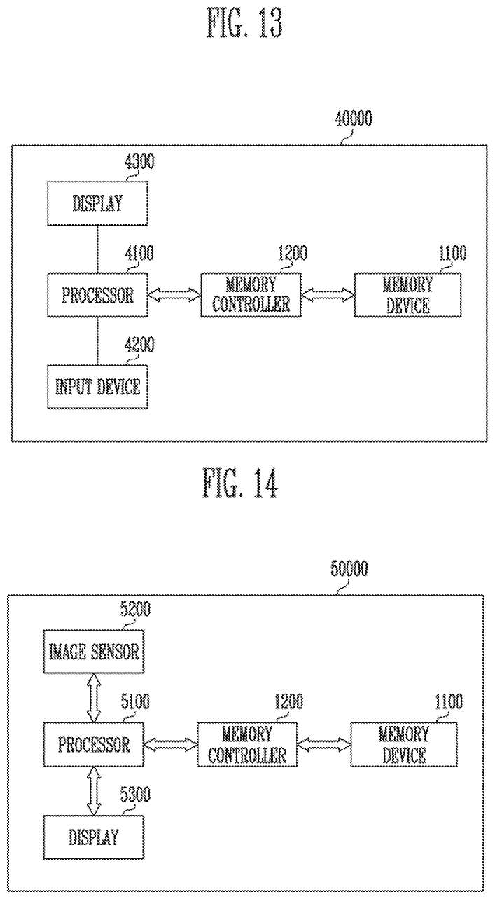

FIG. 14 is a diagram, illustrating another embodiment of the memory system.

Referring to FIG. 14, the memory system 50000 may be implemented as an image processing device, e.g., a digital camera, a mobile terminal having a digital camera attached thereto, a smart phone having a digital camera attached thereto, or a tablet PC having a digital camera attached thereto.

The memory system 50000 may include a memory device 1100 and a memory controller 1200 capable of controlling a data processing operation of the memory device 1100, e.g., a program operation, an erase operation, or a read operation.

An image sensor 5200 of the memory system 50000 may convert an optical image into digital signals, and the converted digital signals may be transmitted to a processor 5100 or the memory controller 1200. Based on the processor 5100, the converted digital signals may be output through a display 5300, or be stored in the memory device 1100 through the memory controller 1200. In addition, data stored in the memory device 1100 may be output through the display 5300 based on the processor 5100 or the memory controller 1200.

In some embodiments, the memory controller 1200 capable of controlling an operation of the memory device 1100 may be implemented as a part of the processor 5100, or be implemented as a chip separate from the processor 5100. Also, the memory controller 1200 may be implemented with the memory controller 1200 shown in FIG. 1, and the memory device 1100 may be implemented with the memory device 1100 shown in FIG. 2.

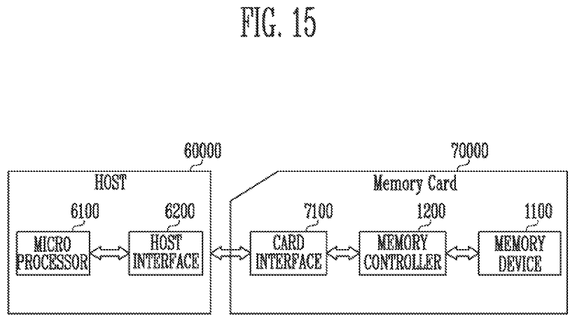

FIG. 15 is a diagram, illustrating another embodiment of the memory system.

Referring to FIG. 15, the memory system 70000 may be implemented as a memory card or a smart card. The memory system 70000 may include a memory device 1100, a memory controller 1200, and a card interface 7100.

The memory controller 1200 may control data exchange between the memory device 1100 and the card interface 7100. In some embodiments, the card interface 7100 may be a secure digital (SD) card interface or a multi-media card (MMC) interface, but the present disclosure is not limited thereto. Also, the memory controller 1200 may be implemented with the memory controller 1200 shown in FIG. 1, and the memory device 1100 may be implemented with the memory device 1100 shown in FIG. 2.

The card interface 7100 may interface data exchange between a host 60000 and the memory controller 1200 based on a protocol of the host 60000. In some embodiments, the card interface 7100 may support a universal serial bus (USB) protocol and an inter-chip (IC)-USB protocol.

The card interface 7100 may mean hardware capable of supporting a protocol used by the host 60000, software embedded in the hardware, or a signal transmission scheme.

When the memory system 70000 is coupled to a host interface 6200 of the host 60000 such as a PC, a tablet PC, a digital camera, a digital audio player, a cellular phone, console video game hardware, or a digital set-top box, the host interface 6200 may perform data communication with the memory device 1100 through the card interface 7100 and the memory controller 1200 based on a microprocessor 6100.

In accordance with the present disclosure, it is determined whether a memory block of which program operation has been completed is a bad block, based on a program count number of the memory block, so that the reliability of data stored in the memory block can be improved.

While the present disclosure has been shown and described with reference to certain exemplary embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described exemplary embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the exemplary embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a memory cell array including a plurality of memory blocks;
peripheral circuits configured to perform a program operation on a selected memory block among the plurality of memory blocks and configured to program memory cells that are included in the selected memory block to a plurality of program states during the program operation; and
a control logic configured to control the peripheral circuits to perform the program operation,
wherein the control logic is configured to count a program pulse number that is used during the program operation and configured to determine whether the selected memory block is a bad block, based on the counted program pulse number.

2. The memory device of claim 1, wherein, during the program operation, the control logic is configured to calculate a plurality of program pulse difference values that correspond to each of the plurality of program states and configured to compare the plurality of calculated program pulse difference values to a plurality of reference difference values that correspond to the plurality of program states.

3. The memory device of claim 2, wherein, during the program operation based on a selected program state among the plurality of program states, the control logic is configured to check a first program pulse count and a last program pulse count of the selected program state and configured to calculate a difference between the checked first program pulse count and the checked last program pulse count, resulting in a program pulse difference value of the selected program state.

4. The memory device of claim 3, wherein the control logic is configured to determine the selected memory block to be the bad block when the program pulse difference value of the selected program state is greater than a reference difference value, among the plurality of reference difference values, that corresponds to the selected program state.

5. The memory device of claim 3, wherein the control logic is configured to control the peripheral circuits to perform the program operation by sequentially selecting the plurality of program states.

6. The memory device of claim 2, wherein the plurality of reference difference values are equal to or different from each other.

7. The memory device of claim 1, wherein the control logic includes:
a program pulse counter configured to count the program pulse number during the program operation, and check a first program pulse count and a last program pulse count of each of the plurality of program states;
a calculation circuit configured to calculate a plurality of count difference values, corresponding to each of the plurality of program states, based on the first program pulse count and the last program pulse count;
a comparison circuit configured to output a pass signal or a fail signal based on a comparison between the plurality of count difference values and a plurality of reference difference values that correspond to each of the plurality of program states; and
a bad block information generation circuit configured to generate and output bad block information, including determination information of the selected memory block, based on the pass signal or the fail signal.

8. The memory device of claim 7, wherein the first program pulse count is a program pulse count when a firstly program-passed memory cell is detected during a program verify operation based on the selected program state among the plurality of program states, and
wherein the last program pulse count is a program pulse count when a lastly program-passed memory cell is detected during the program verify operation based on the selected program state among the plurality of program states.

9. A memory device comprising:
a memory cell array including a plurality of memory blocks;
peripheral circuits configured to perform a program operation on a selected memory block among the plurality of memory blocks and configured to program memory cells that are included in the selected memory block to a plurality of program states during the program operation; and
a control logic configured to control the peripheral circuits to perform the program operation,
wherein the control logic is configured to set a plurality of program pulse count ranges by counting a program pulse number used during the program operation and configured to determine whether the selected memory block is a bad block, based on a number of memory cells that are out of the plurality of set program pulse count ranges.

10. The memory device of claim 9, wherein the control logic is configured to calculate a plurality of program pulse count average values that correspond to each of the plurality of program states during the program operation.

11. The memory device of claim 10, wherein, during the program operation based on a selected program state among the plurality of program states, the control logic is configured to check a first program pulse count and a last program pulse count of the selected program state and configured to calculate a program pulse count average value based on the selected program state by using the checked first program pulse count and the checked last program pulse count.

12. The memory device of claim 10, wherein the control logic is configured to set the plurality of program pulse count ranges based on the plurality of calculated program pulse count average values.

13. The memory device of claim 9, wherein the control logic is configured to determine the selected memory block to be the bad block when the number of memory cells that are out of the plurality of set program pulse count ranges is greater than a reference cell number.

14. The memory device of claim 9, wherein the control logic includes:
a program pulse counter configured to count the program pulse number during the program operation and configured to output a first program pulse count and a last program pulse count of each of the plurality of program states;
a calculation circuit configured to calculate a plurality of program pulse count average values, corresponding to each of the plurality of program states, based on the first program pulse count and the last program pulse count of each of the plurality of program states, and configured to set the plurality of program pulse count ranges, corresponding to each of the plurality of program states, based on the plurality of calculated program pulse count average values;
a cell number counter configured to output a memory cell number count by counting a number of memory cells that are determined to be program pass in each program pulse during the program operation;
a register configured to receive and store the plurality of program pulse count ranges and the memory cell number count, and configured to generate and output a plurality of cell count out signals that represents the number of memory cells that are out of the plurality of set program pulse count ranges;
a comparison circuit configured to output a pass signal or a fail signal based on a comparison between the number of memory cells that are out of the plurality of set program pulse count ranges and a reference memory cell number, based on the plurality of cell count out signals that corresponds to each of the plurality of program states; and
a bad block information generation circuit configured to generate and output bad block information, including determination information of the selected memory block, based on the pass signal or the fail signal.

15. The memory device of claim 14, wherein the first program pulse count is a program pulse count when a firstly program-passed memory cell is detected during a program verify operation based on the selected program state among the plurality of program states, and
wherein the last program pulse count is a program pulse count when a lastly program-passed memory cell is detected during the program verify operation based on the selected program state among the plurality of program states.

16. A memory device comprising:
a memory block including a plurality of pages;
peripheral circuits configured to perform a program operation on the memory block and configured to perform the program operation by sequentially selecting the plurality of pages during the program operation; and
a control logic configured to control the peripheral circuits to perform the program operation,
wherein the control logic is configured to count program pulses of each of the plurality of pages and configured to determine whether the memory block is a bad block, based on the program pulses of each of the plurality of pages.

17. The memory device of claim 16, wherein the control logic is configured to calculate a program pulse average value by using the program pulse counts of each of the plurality of pages.

18. The memory device of claim 17, wherein the control logic is configured to calculate a difference value based on a difference between the program pulse average value and the counted program pulses of each of the plurality of pages.

19. The memory device of claim 16, wherein the memory block is determined to be the bad block when at least one page, among the plurality of pages, is detected to have a difference value that is equal to or greater than a reference value, and
wherein the control logic is configured to calculate the difference value based on a difference between the program pulse average value and the counted program pulses of each of the plurality of pages.

20. The memory device of claim 16, wherein the control logic includes:
a program pulse counter configured to check a first program pulse count and a last program pulse count of each of the plurality of pages during the program operation and configured to generate program pulse counts of each of the plurality of pages by calculating an average value of the initial program pulse count and the last program pulse count;
a register configured to store the program pulse counts of each of the plurality of pages;
a calculation circuit configured to calculate a program pulse count average value of all the pages, based on the program pulse counts that are stored in the register, and configured to calculate page count difference values of each of the plurality of pages based on the program pulse count average value and the program pulse counts of each of the plurality of pages;
a comparison circuit configured to generate a pass signal or a fail signal based on a comparison between the page count difference values and a reference difference value; and
a bad block information generation circuit configured to generate and output bad block information, including determination information of the memory block, based on the pass signal or the fail signal.
